(19) United States
(12) Patent Application Publication
(10) Pub. No.: US 2026/0190923 A1
(43) Pub. Date: Jul. 2, 2026

(54) LIQUID SUPPLY UNIT AND SUBSTRATE PROCESSING APPARATUS INCLUDING LIQUID SUPPLY UNIT

(71) Applicant: SEMES CO., LTD., Cheonan-si (KR)

(72) Inventor: Jong Min LEE, Yongin-si (KR)

(21) Appl. No.: 19/397,811

(22) Filed: Nov. 21, 2025

(30) Foreign Application Priority Data
Dec. 30, 2024 (KR) 10-2024-0200459

(51) Int. Cl. H01L 21/67

(52) U.S. Cl. CPC H10P 72/0606; H10P 72/0414; H10P 72/0604

(57) ABSTRACT

A liquid supply unit includes a nozzle configured to discharge a processing liquid through a discharge passage formed therein, a camera configured to acquire an image of the nozzle, and a detection unit configured to detect a position of a liquid level within the discharge passage from the image of the nozzle. The detection unit is configured to derive an edge profile by processing the image of the nozzle, to derive one or more search regions by dividing the edge profile, and to detect the liquid level within the one or more search regions.

### CROSS-REFERENCE TO RELATED APPLICATION(S)

This application claims benefit of priority to Korean Patent Application No. 10-2024-0200459 filed on Dec. 30, 2024 in the Korean Intellectual Property Office, the disclosure of which is incorporated herein by reference in its entirety.

### BACKGROUND

### 1. Field

The present disclosure relates to a liquid supply unit and a substrate processing apparatus including the same.

### 2. Description of Related Art

Various processes may be performed on a substrate to manufacture a semiconductor device. Among the various processes, a photolithography process may be an essential process for forming a pattern on the substrate.

The photolithography process may include a coating process of coating a photosensitive liquid, such as a photoresist, on the substrate. A technique of uniformly coating the photosensitive liquid having viscosity on the substrate to a predetermined thickness may be significantly crucial.

Therefore, it may be required to accurately supply the photosensitive liquid from a nozzle at a predetermined flow rate onto the substrate. To this end, the liquid may be sucked back not only when the nozzle supplies the liquid but also when liquid supply is stopped, in order to prevent the liquid from falling or being contaminated.

In addition, while the nozzle is in a standby state, another liquid may be additionally sucked back to prevent the liquid in the nozzle from being cured due to contact with air. Accordingly, a technique capable of verifying whether such a suck-back process is appropriately performed may be required.

### SUMMARY

An aspect of the present disclosure is to provide a liquid supply unit and a substrate processing apparatus including the same, capable of accurately detecting a position of a liquid level within a nozzle on which a multi suck-back process is performed.

Another aspect of the present disclosure is to provide a liquid supply unit and a substrate processing apparatus including the same capable of deriving an edge profile by processing an image of a nozzle, deriving one or more search regions by dividing the edge profile, and detecting a position of a liquid level using an inflection point within the one or more search regions.

Another aspect of the present disclosure is to provide a liquid supply unit and a substrate processing apparatus including the same, capable of avoiding false detection due to a residual chemical solution within a nozzle or other contamination, and improving accuracy of liquid level detection by dynamically setting a search region for detecting a liquid level positioned between two different liquid levels.

The aspects of the present disclosure are not limited to those set forth herein. A person having ordinary skill in the art to which the present disclosure pertains may have no difficulty in understanding additional aspects of the present disclosure from the overall contents of the present specification.

According to an aspect of the present disclosure, there is provided a liquid supply unit including a nozzle configured to discharge a processing liquid through a discharge passage formed therein, a camera configured to acquire an image of the nozzle, and a detection unit configured to detect a position of a liquid level within the discharge passage from the image of the nozzle. The detection unit may be configured to derive an edge profile by processing the image of the nozzle, to derive one or more search regions by dividing the edge profile, and to detect the liquid level within the one or more search regions.

According to another aspect of the present disclosure, there is provided a substrate processing apparatus including a support unit configured to support a substrate, a liquid supply unit including a nozzle configured to supply a processing liquid onto the substrate, an imaging unit configured to capture an image of the nozzle, and a detection unit configured to detect a position of a liquid level in a discharge passage within the nozzle from the image of the nozzle. The detection unit may be configured to derive an edge profile by processing the image of the nozzle, to derive one or more search regions by dividing the edge profile, and to detect the liquid level within the one or more search regions.

According to another aspect of the present disclosure, there is provided a substrate processing apparatus including a support unit configured to support a substrate, a liquid supply unit including a nozzle configured to supply a processing liquid onto the substrate, and a nozzle support member configured to support the nozzle, a standby unit disposed to be spaced apart from the support unit, the standby unit configured to accommodate the nozzle and provide a contamination prevention liquid to the nozzle, an imaging unit configured to capture an image of the nozzle including a discharge passage formed within the nozzle and a shape of the processing liquid, and a detection unit configured to detect a position of a liquid level of the processing liquid or the contamination prevention liquid within the discharge passage from the image of the nozzle. The detection unit may be configured to derive an edge profile by processing the image of the nozzle, to derive one or more search regions by dividing the edge profile, and to detect the liquid level within the one or more search regions.

According to example embodiments of the present disclosure, a liquid supply unit and a substrate processing apparatus including the same may accurately detect a position of a liquid level within a nozzle on which a multi suck-back process is performed.

According to example embodiments of the present disclosure, a liquid supply unit and a substrate processing apparatus including the same may derive an edge profile by processing an image of a nozzle, derive one or more search regions by dividing the edge profile, and detect a position of a liquid level using an inflection point within the one or more search regions.

According to example embodiments of the present disclosure, a liquid supply unit and a substrate processing apparatus including the same may avoid false detection due to a residual chemical solution within a nozzle or other contamination and improve accuracy of liquid level detection by dynamically setting a search region for detecting a liquid level positioned between two different liquid levels.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 illustrates a substrate processing apparatus according to an example embodiment of the present disclosure;

FIG. 2 illustrates an image of a nozzle acquired in a substrate processing apparatus according to an example embodiment of the present disclosure;

FIG. 3 illustrates an edge profile derived from an image of a nozzle illustrated in FIG. 2;

FIG. 4A is a diagram illustrating a method of detecting a position of a liquid level in a substrate processing apparatus according to an example embodiment of the present disclosure;

FIG. 4B illustrates a section of an edge profile corresponding to a search region illustrated in FIG. 4A;

FIG. 5A is a diagram illustrating a method of detecting a position of a liquid level in a substrate processing apparatus according to an example embodiment of the present disclosure;

FIG. 5B illustrates a section of an edge profile corresponding to a search region illustrated in FIG. 5A;

FIG. 6 illustrates a detected position of a liquid level according to an example embodiment of the present disclosure;

FIG. 7 illustrates a process of detecting a position of a liquid level from an image of a nozzle according to an example embodiment of the present disclosure; and

FIG. 8 is a block diagram of a computing device in which a method of detecting a position of a liquid level of a nozzle by a substrate processing apparatus according to an example embodiment of the present disclosure may be fully or partially implemented.

### DETAILED DESCRIPTION

Hereinafter, preferred example embodiments are described in detail with reference to the accompanying drawings such that those skilled in the art can readily practice the present disclosure. However, the example embodiments of the present disclosure may be modified into various other forms, and the scope of the present disclosure is not limited to the example embodiments described below.

In addition, example embodiments of the present disclosure are provided to further describe the present disclosure to those skilled in the art.

In the drawings, shapes, sizes, and the like of elements may be exaggerated or reduced for clearer illustration.

In describing the example embodiments of the present disclosure, when it is determined that a detailed description of a known technology related to the present disclosure may unnecessarily obscure the gist of the present disclosure, the detailed description thereof will be omitted. In addition, terms to be described below are terms defined in consideration of functions in the present disclosure, which may vary depending on intention or custom of a user or operator. Therefore, the definition of these terms should be made based on the contents throughout the present specification. The terminology used herein is for the purpose of describing particular example embodiments only and is not to be limiting of the example embodiments. As used herein, the singular forms “a,” “an,” and “the” are intended to include the plural forms as well, unless the context clearly indicates otherwise.

In addition, in the present specification, terms such as “upper,” “upper portion,” “upper surface,” “lower,” “lower portion,” “lower surface,” and “side surface” are based on the drawings, may vary depending on a direction in which an element or component is actually disposed.

When it is mentioned that one component is “connected” or “accessed” to another component, it may be understood that the one component is directly connected or accessed to another component or that still other component is interposed between the two components. In addition, it should be noted that if it is described in the specification that one component is “directly connected” or “directly joined” to another component, still other component may not be present therebetween. In addition, it will be understood that “comprises” and/or “comprising” specify the presence of stated features, integers, steps, operations, elements, components or a combination thereof, but do not preclude the presence or addition of one or more other features, integers, steps, operations, elements, components, and/or groups thereof.

Hereinafter, the present disclosure will be described in detail through each example embodiment or example. It should be noted that each example embodiment or example described herein is not limited to a single example embodiment or example, and combinations with other example embodiments or examples are also possible. Accordingly, citation of claims in the claims section correspond to only one example of an example embodiment, and the technical concept of the present disclosure should not be construed as being limited to combinations with the cited claims. Combinations with various claims are also within the scope of the technical concept of the present disclosure.

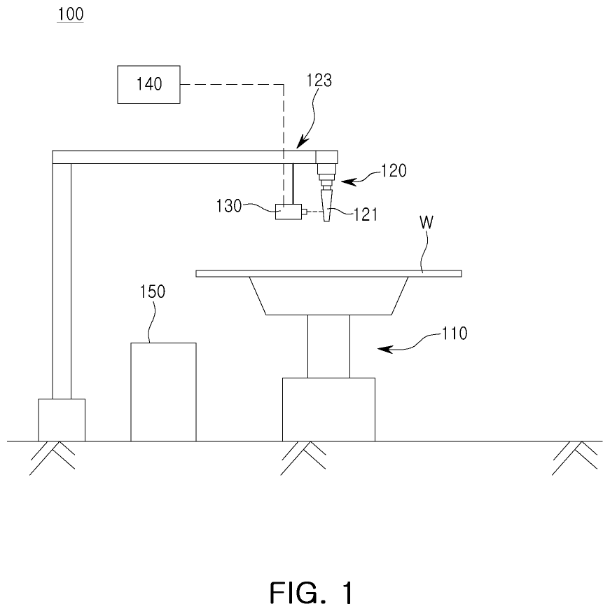

FIG. 1 illustrates a substrate processing apparatus according to an example embodiment of the present disclosure.

A substrate processing apparatus 100 may supply a processing liquid onto a substrate W, and may perform a process on the substrate W. The processing liquid may be, for example, a photoresist liquid.

The substrate processing apparatus 100 may include a support unit 110, a liquid supply unit 120, an imaging unit 130, a detection unit 140, and a standby unit 150.

The support unit 110 may support the substrate W, and may rotate the substrate W.

The liquid supply unit 120 may include a nozzle 121 and a nozzle support member 123.

The nozzle 121 may discharge the processing liquid through a discharge passage formed therein. The processing liquid may be, for example, a photoresist liquid.

The nozzle 121 may perform a first suck-back process of retracting the processing liquid in a direction, opposite to a discharge direction in the discharge passage. For example, the first suck-back process may be performed after discharge of the processing liquid onto the substrate W is completed.

By the first suck-back process, air may be suctioned into the discharge passage, and a processing liquid layer and an air layer may be formed in the discharge passage.

The nozzle support member 123 may support the nozzle 121, and may move the nozzle 121 in a horizontal direction or in a vertical direction. The nozzle support member 123 may support the nozzle 121 from above.

The nozzle support member 123 may move the nozzle 121 onto the substrate W, in a state of supporting the nozzle 121.

The imaging unit 130 may acquire an image of the nozzle 121. The imaging unit 130 may include a camera.

The nozzle 121 may be formed of a material that is at least partially transparent. The image of the nozzle 121 may include an outline of the nozzle 121, a shape of the discharge passage within the nozzle 121, and a shape of a fluid positioned in the discharge passage.

In an example embodiment, the imaging unit 130 may be installed on the nozzle support member 123, as illustrated in FIG. 1.

In another example embodiment, the imaging unit 130 may be installed in another position of the substrate processing apparatus 100 to acquire the image of the nozzle 121.

The detection unit 140 may detect a position of a liquid level within the discharge passage from the image of the nozzle 121. The liquid level may be formed at a boundary between a chemical solution layer and an air layer within the discharge passage.

The detection unit 140 may process the image of the nozzle 121 to derive an edge profile. For example, the detection unit 140 may derive the edge profile, based on a variation in a pixel value included in the image of the nozzle 121.

The detection unit 140 may derive a Y-axis edge profile corresponding to the image of the nozzle 121. The detection unit 140 may divide the edge profile to derive one or more search regions.

The detection unit 140 may detect a liquid level within the one or more search regions. The detection unit 140 may detect a position of the liquid level using at least one of inflection points positioned within the one or more search regions.

The detection unit 140 may derive the position of the liquid level from the edge profile, using a peak finding algorithm.

The detection unit 140 may perform one or more of a noise removal process, an edge enhancement process, a contrast improvement process, and an edge extraction process on the image of the nozzle 121 to improve accuracy of liquid level detection.

The standby unit 150 may provide a place in which the nozzle 121 is in a standby state while the nozzle 121 does not discharge the processing liquid onto the substrate W. The standby unit 150 may be installed to be spaced apart from the support unit 110.

The standby unit 150 may accommodate a portion of the nozzle 121. The standby unit 150 may provide a contamination prevention liquid to the nozzle 121.

The nozzle support member 123 may move the nozzle 121 to the standby unit 150 in a state of supporting the nozzle 121.

The nozzle 121 may perform a multi suck-back process, in which a suck-back process is performed a plurality of times, to effectively prevent contamination of the processing liquid. The nozzle 121 may perform a second suck-back process of suctioning a contamination prevention liquid from below the discharge passage and retracting the processing liquid and the contamination prevention liquid in the discharge passage in the direction, opposite to the discharge direction.

For example, the second suck-back process may be performed while the nozzle 121 is in a standby state at the standby unit 150.

The first suck-back process and the second suck-back process may be sequentially performed. By the first suck-back process and second suck-back process, a lower air layer, a contamination prevention liquid layer, an intermediate air layer, and a processing liquid layer may be sequentially formed from a lower end of the nozzle 121 within a discharge passage of the nozzle 121.

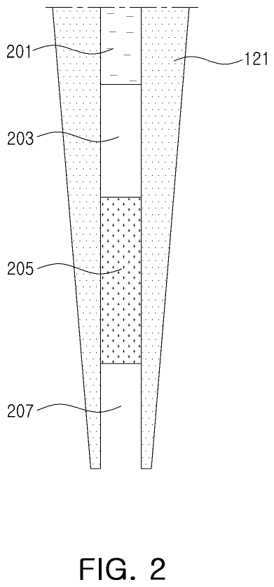

FIG. 2 illustrates an image of the nozzle 121 on which a multi suck-back process is performed. The image of the nozzle 121 may include a discharge passage, a processing liquid positioned within the discharge passage, a chemical solution such as a contamination prevention liquid, and a shape of air.

The processing liquid layer 201, the intermediate air layer 203, the contamination prevention liquid layer 205, and the lower air layer 207 may be stacked in order of being first suctioned into the discharge passage by the multi suck-back process of the nozzle 121.

The detection unit 140 may acquire the image of the nozzle 121 on which the multi suck-back process is performed, and may detect a position of a liquid level within the discharge passage from the image of the nozzle 121.

The detection unit 140 may detect a plurality of liquid levels. The plurality of liquid levels may include a first liquid level between the processing liquid layer 201 and the intermediate air layer 203, a second liquid level between the contamination prevention liquid layer 205 and the lower air layer 207, and a third liquid level between the intermediate air layer 203 and the contamination prevention liquid layer 205.

Specifically, the detection unit 140 may derive an edge profile by processing the image of the nozzle 121, as illustrated in FIG. 2. The edge profile may include, for example, information on a variation in a pixel value included in the image of the nozzle 121.

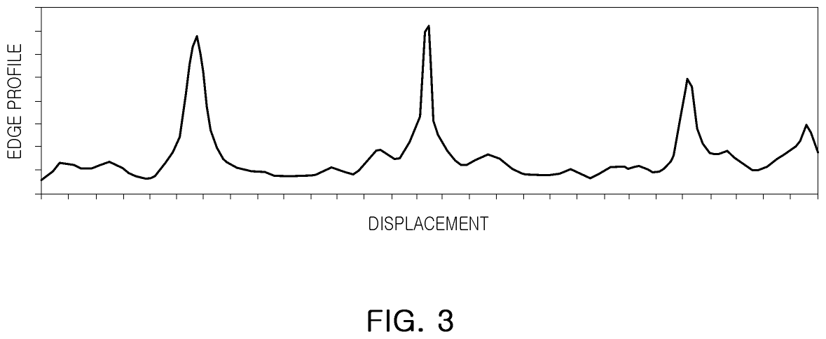

FIG. 3 illustrates a Y-axis edge profile derived from the image of the nozzle illustrated in FIG. 2. Referring to FIG. 3, the edge profile derived from the image of the nozzle may have a peak value at a boundary between different materials.

The detection unit 140 may derive one or more search regions, based on the image of the nozzle 121. The detection unit 140 may detect a liquid level, based on shapes of edge profiles of the one or more search regions.

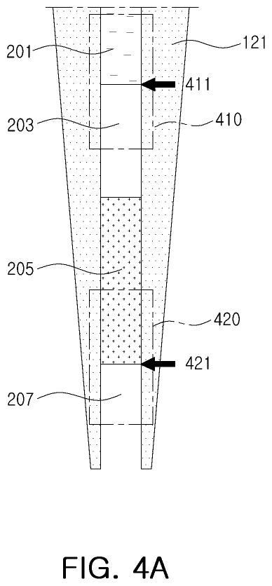

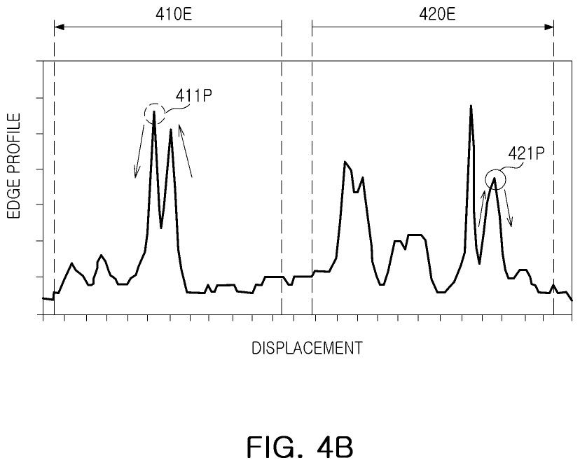

For example, as illustrated in FIGS. 4A and 4B, the detection unit 140 may derive a first search region including a section of the edge profile corresponding to a first liquid level 411, based on the image of the nozzle 121.

The first liquid level 411 may include a boundary between the processing liquid layer 201 and the intermediate air layer 203.

Specifically, in FIG. 4A, a first box 410, including the boundary between the processing liquid layer 201 and the intermediate air layer 203, may be set. As illustrated in FIG. 4B, the detection unit 140 may determine, as a first search region 410E, a section of the edge profile corresponding to the first box 410 in the image of the nozzle 121.

The detection unit 140 may detect the first liquid level 411, based on a shape of an edge profile of the first search region 410E.

The detection unit 140 may set a search direction for the edge profile, based on a direction in which less noise occurs.

In an example embodiment, the detection unit 140 may search the edge profile in a first direction from the intermediate air layer 203 toward the processing liquid layer 201 with respect to the first search region 410E.

The detection unit 140 may detect the first liquid level 411, using a peak finding algorithm.

For example, the detection unit 140 may determine at least one of inflection points, included in the edge profile of the first search region 410E as a first peak 411P corresponding to the first liquid level 411.

The detection unit 140 may detect the first liquid level 411, based on whether the edge profile has a value within a predetermined range, and a shape and a position of the inflection point of the edge profile.

In the same manner, as illustrated in FIGS. 4A and 4B, the detection unit 140 may derive a second search region including a section of the edge profile corresponding to a second liquid level 421, based on the image of the nozzle 121.

Here, the second liquid level 421 may include a boundary between the contamination prevention liquid layer 205 and the lower air layer 207.

Specifically, in FIG. 4A, a second box 420, including the boundary between the contamination prevention liquid layer 205 and the lower air layer 207, may be set. As illustrated in FIG. 4B, the detection unit 140 may determine, as a second search region 420E, a section of the edge profile corresponding to the second box 420 in the image of the nozzle 121.

The detection unit 140 may detect the second liquid level 421, based on a shape of an edge profile of the second search region 420E.

The detection unit 140 may set a search direction for the edge profile, based on a direction in which less noise occurs.

In an example embodiment, the detection unit 140 may search the edge profile of the second search region 420E in a second direction from the contamination prevention liquid layer 205 toward the lower air layer 207.

The detection unit 140 may detect the second liquid level 421 using a peak finding algorithm.

For example, the detection unit 140 may determine at least one of inflection points included in the edge profile of the second search region 420E as a second peak 421P corresponding to the second liquid level 421.

The detection unit 140 may set a third search region for detecting a third liquid level, based on a position of the first liquid level 411 and a position of the second liquid level 421.

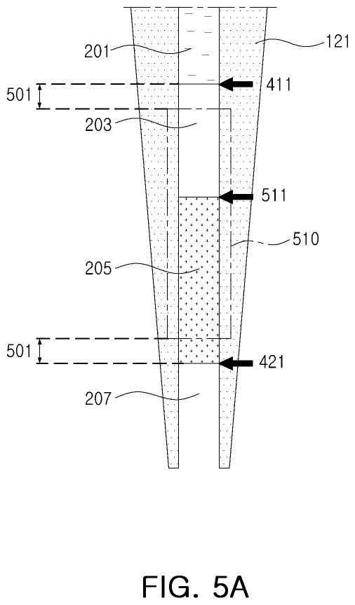

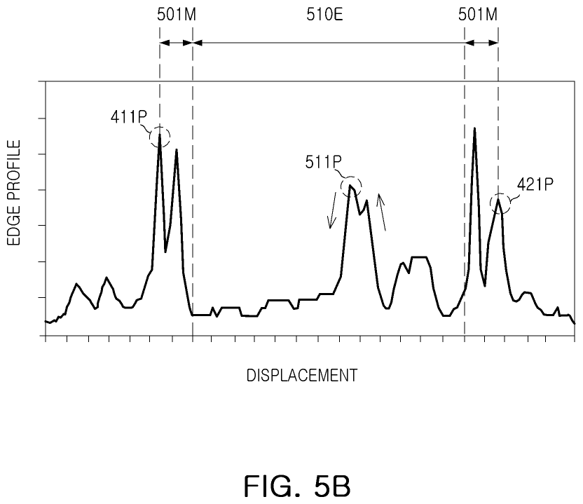

For example, as illustrated in FIGS. 5A and 5B, the detection unit 140 may derive a third search region for detecting a third liquid level 511.

The third liquid level 511 may include a boundary between the intermediate air layer 203 and the contamination prevention liquid layer 205.

Specifically, in FIG. 5A, a third box 510 may be set in a range spaced apart from the first liquid level 411 by a predetermined distance 501 and spaced apart from the second liquid level 421 in an upward direction by the predetermined distance 501.

As illustrated in FIG. 5B, the detection unit 140 may determine, as a third search region 510E, a section of the edge profile corresponding to the third box 510 in the image of the nozzle 121. In the edge profile of FIG. 5B, a distance 501M spaced apart from the first liquid level 411 and the second liquid level 421 may appear.

The detection unit 140 may detect the third liquid level 511, based on a shape of an edge profile of the third search region 510E.

The detection unit 140 may set a search direction for the edge profile, based on a direction in which less noise occurs.

In an example embodiment, the detection unit 140 may search the edge profile of the third search region 510E in a third direction from the contamination prevention liquid layer 205 toward the intermediate air layer 203. The third direction may be the same as the first direction and opposite to the second direction.

In another example embodiment, the detection unit 140 may search the edge profiles of the first to third search regions in the same direction.

The detection unit 140 may detect the first liquid level 411 using a peak finding algorithm.

For example, the detection unit 140 may determine at least one of inflection points included in the edge profile of the first search region 410E as a first peak 411P corresponding to the first liquid level 411.

The detection unit 140 may detect the first liquid level 411 based on whether the edge profile has a value within a predetermined range, and a shape and a position of the inflection point of the edge profile.

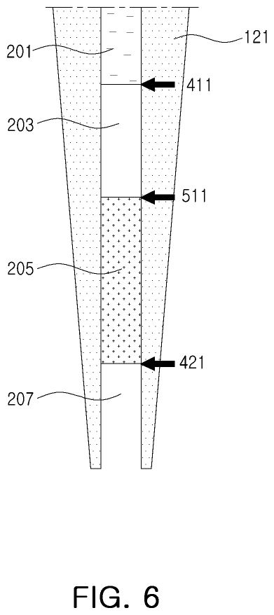

FIG. 6 illustrates a detected position of a liquid level according to an example embodiment of the present disclosure. As illustrated in FIG. 6, a plurality of liquid levels, formed within a discharge passage of the nozzle 121 on which a multi suck-back process is performed, may be detected.

The plurality of liquid levels may include a first liquid level 411 between the processing liquid layer 201 and the intermediate air layer 203, a second liquid level 421 between the contamination prevention liquid layer 205 and the lower air layer 207, and a third liquid level 511 between the intermediate air layer 203 and the contamination prevention liquid layer 205.

According to the present disclosure, a first liquid level and a second liquid level may be pre-detected, and a search region for detecting a third liquid level may be dynamically set based on a position of the first liquid level and a position of the second liquid level, thereby effectively detecting a plurality of liquid levels formed within a nozzle on which a multi suck-back operation is performed.

According to the present disclosure, an edge profile may be derived from an image of a nozzle, one or more search regions may be derived by dividing the edge profile, and a liquid level may be detected within the one or more search regions, thereby avoiding false detection due to a residual chemical solution or other contamination within the nozzle, and improving accuracy of liquid level detection.

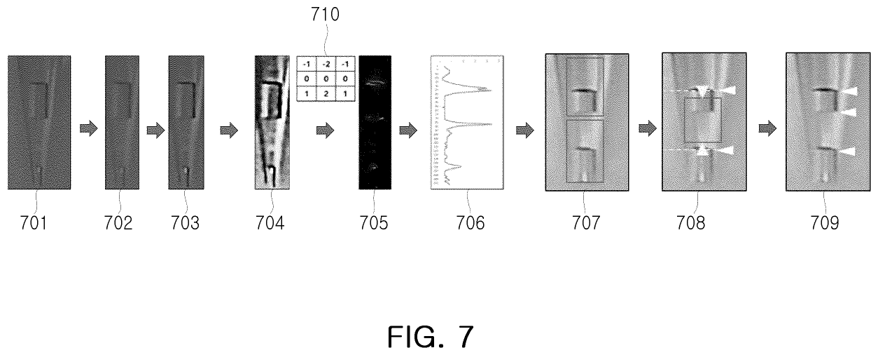

FIG. 7 illustrates a process of detecting a position of a liquid level within a nozzle by a substrate processing apparatus according to an example embodiment of the present disclosure.

An original nozzle image captured using a camera may be acquired (701), and a noise removal process (702), an edge enhancement process (703), a contrast improvement process (704), and an edge component extraction and secondary noise removal process (705) may be sequentially performed on the nozzle image. Edge component extraction may be performed using a filter 710, as illustrated in FIG. 7.

Subsequently, a Y-axis edge profile 706 may be derived, and a first search region and a second search region may be set using the nozzle image and the Y-axis edge profile (707). A first liquid level and a second liquid level may be respectively detected from the first search region and the second search region (708).

A third search region for detecting a third liquid level, positioned between the first liquid level and the second liquid level, may be set based on a position of the first liquid level and a position of the second liquid level (708). The third liquid level may be detected from the third search region (709).

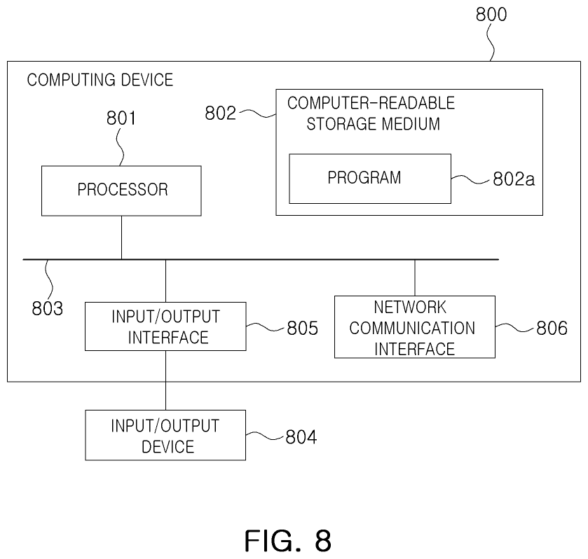

FIG. 8 is a block diagram of a computing device 800 in which a method of detecting a position of a liquid level of a nozzle by a substrate processing apparatus according to an example embodiment of the present disclosure may be implemented in whole or in part. The computing device 800 may be the detection unit of the substrate processing device described with reference to FIGS. 1 to 7.

As illustrated in FIG. 8, the computing device 800 may include at least one processor 801, a computer-readable storage medium 802, and a communication bus 803.

The processor 801 may cause the computing device 800 to operate according to the example embodiments described above. For example, the processor 801 may execute one or more programs stored on the computer-readable storage medium 802. The one or more programs may include one or more computer-executable instructions, which, when executed by the processor 801, may be configured to cause the computing device 800 to perform operations according to example embodiments.

The computer-readable storage medium 802 may be configured to store the computer-executable instruction or program code, program data, and/or other suitable forms of information. A program 802a stored in the computer-readable storage medium 802 may include a set of instructions executable by the processor 801. In an example embodiment, the computer-readable storage medium 802 may be a memory (volatile memory such as a random access memory, non-volatile memory, or any suitable combination thereof), one or more magnetic disk storage devices, optical disk storage devices, flash memory devices, other types of storage media that are accessible by the computing device 800 and are capable of storing desired information, or any suitable combination thereof.

The communication bus 803 may interconnect various other components of the computing device 800, including the processor 801 and the computer-readable storage medium 802.

The computing device 12 may also include one or more input/output interfaces 805 providing an interface for one or more input/output devices 804, and one or more network communication interfaces 806. The input/output interface 805 and the network communication interface 806 may be connected to the communication bus 803.

The input/output device 804 may be connected to other components of the computing device 800 through the input/output interface 805. The exemplary input/output device 804 may include a pointing device (such as a mouse or trackpad), a keyboard, a touch input device (such as a touchpad or touchscreen), a voice or sound input device, input devices such as various types of sensor devices and/or photographing devices, and/or output devices such as a display device, a printer, a speaker, and/or a network card. The exemplary input/output device 804 may be included in the computing device 800 as a component included in the computing device 800, or may be connected to the computing device 800 as a device distinct from the computing device 800.

Example embodiments of the present disclosure may include a program for performing the methods described herein on a computer, and a computer-readable recording medium including the program. The computer-readable recording medium may include, alone or in combination with program instructions, local data files, local data structures, and the like. The medium may be those specially designed and constructed for the purposes of the example embodiments, or may be of the well-known kind and available to those having skill in the computer software arts. Examples of the computer-readable medium include magnetic media such as hard disks, floppy disks, and magnetic tape, optical media such as CD ROM discs and DVDs, magneto-optical media such as optical discs, and hardware devices that are specially configured to store and perform program instructions, such as read-only memory (ROM), random access memory (RAM), flash memory, and the like. Examples of the program may include both a machine code, such as a code produced by a compiler, and a higher level code that may be executed by the computer using an interpreter.

While example embodiments have been illustrated and described above, it will be apparent to those skilled in the art that modifications and variations could be made without departing from the scope of the present disclosure as defined by the appended claims. Therefore, the scope of the present disclosure should not be limited to the described example embodiments, and should be defined not only by the following claims but also by equivalents thereof.

What is claimed is:

1. A liquid supply unit comprising:
a nozzle configured to discharge a processing liquid through a discharge passage formed therein;
a camera configured to acquire an image of the nozzle; and
a detection unit configured to detect a position of a liquid level within the discharge passage from the image of the nozzle,
wherein the detection unit is configured to derive an edge profile by processing the image of the nozzle, to derive one or more search regions by dividing the edge profile, and to detect the liquid level within the one or more search regions.

2. The liquid supply unit of claim 1, wherein the liquid supply unit is configured to:
perform a first suck-back process of retracting the processing liquid in the discharge passage in a direction, opposite to a discharge direction; and
perform a second suck-back process of retracting a contamination prevention liquid in the discharge passage in the direction, opposite to the discharge direction, after the first suck-back process is performed, and
the liquid supply unit is configured to sequentially form a lower air layer, a contamination prevention liquid layer, an intermediate air layer, and a processing liquid layer from a lower end of the nozzle within the discharge passage.

3. The liquid supply unit of claim 2, wherein the detection unit is configured to detect:
a first liquid level between the processing liquid layer and the intermediate air layer;
a second liquid level between the contamination prevention liquid layer and the lower air layer; and
a third liquid level between the intermediate air layer and the contamination prevention liquid layer.

4. The liquid supply unit of claim 3, wherein the detection unit is configured to:
derive, based on the image of the nozzle, a first search region including a section of the edge profile corresponding to the first liquid level; and
derive, based on the image of the nozzle, a second search region including a section of the edge profile corresponding to the second liquid level.

5. The liquid supply unit of claim 4, wherein the detection unit is configured to:
detect the first liquid level, based on a shape of an edge profile of the first search region; and
detect the second liquid level, based on a shape of an edge profile of the second search region.

6. The liquid supply unit of claim 5, wherein the detection unit is configured to:
search the edge profile in a first direction from the intermediate air layer toward the processing liquid layer with respect to the first search region; and
search the edge profile in a second direction from the contamination prevention liquid layer toward the lower air layer with respect to the second search region.

7. The liquid supply unit of claim 5, wherein the detection unit is configured to set, based on a position of the first liquid level and a position of the second liquid level, a third search region for detecting the third liquid level.

8. The liquid supply unit of claim 7, wherein the detection unit is configured to:
derive, as a third search region, a section of the edge profile in the image of the nozzle corresponding to a range spaced apart from the first liquid level in a downward direction by a predetermined distance and spaced apart from the second liquid level in an upward direction by the predetermined distance; and
detect, based on a shape of an edge profile of the third search region, the third liquid level.

9. The liquid supply unit of claim 8, wherein the detection unit is configured to search the edge profile in a third direction from the contamination prevention liquid layer toward the intermediate air layer with respect to the third search region.

10. The liquid supply unit of claim 1, wherein the detection unit is configured to detect, based on an inflection point, the liquid level within the one or more search regions.

11. A substrate processing apparatus comprising:
a support unit configured to support a substrate;
a liquid supply unit including a nozzle configured to supply a processing liquid onto the substrate;
an imaging unit configured to capture an image of the nozzle; and
a detection unit configured to detect a position of a liquid level in a discharge passage within the nozzle from the image of the nozzle,
wherein the detection unit is configured to derive an edge profile by processing the image of the nozzle, to derive one or more search regions by dividing the edge profile, and to detect the liquid level within the one or more search regions.

12. The substrate processing apparatus of claim 11, wherein the substrate processing apparatus is configured to perform:
a first suck-back process of retracting the processing liquid in the discharge passage in a direction, opposite to a discharge direction; and
a second suck-back process of retracting a contamination prevention liquid in the discharge passage in the direction, opposite to the discharge direction, after the first suck-back process is performed,
the substrate processing apparatus is configured to sequentially form a lower air layer, a contamination prevention liquid layer, an intermediate air layer, and a processing liquid layer from a lower end of the nozzle within the discharge passage.

13. The substrate processing apparatus of claim 12, wherein the detection unit is configured to detect:
a first liquid level between the processing liquid layer and the intermediate air layer;
a second liquid level between the contamination prevention liquid layer and the lower air layer; and
a third liquid level between the intermediate air layer and the contamination prevention liquid layer.

14. The substrate processing apparatus of claim 13, wherein the detection unit is configured to:
derive, based on the image of the nozzle, a first search region including a section of the edge profile corresponding to the first liquid level; and
derive, based on the image of the nozzle, a second search region including a section of the edge profile corresponding to the second liquid level.

15. The substrate processing apparatus of claim 14, wherein the detection unit is configured to:
detect the first liquid level, based on a shape of an edge profile of the first search region; and
detect the second liquid level, based on a shape of an edge profile of the second search region.

16. The substrate processing apparatus of claim 15, wherein the detection unit is configured to:
search the edge profile in a first direction from the intermediate air layer toward the processing liquid layer with respect to the first search region; and
search the edge profile in a second direction from the contamination prevention liquid layer toward the lower air layer with respect to the second search region.

17. The substrate processing apparatus of claim 15, wherein the detection unit is configured to set, based on a position of the first liquid level and a position of the second liquid level, a third search region for detecting the third liquid level.

18. The substrate processing apparatus of claim 17, wherein the detection unit is configured to:
derive, as a third search region, a section of the edge profile in the image of the nozzle corresponding to a range spaced apart from the first liquid level in a downward direction by a predetermined distance and spaced apart from the second liquid level in an upward direction by the predetermined distance, and
detect, based on a shape of an edge profile of the third search region, the third liquid level.

19. The substrate processing apparatus of claim 18, wherein the detection unit is configured to search the edge profile in a third direction from the contamination prevention liquid layer toward the intermediate air layer with respect to the third search region.

20. A substrate processing apparatus comprising:
a support unit configured to support a substrate;
a liquid supply unit including a nozzle configured to supply a processing liquid onto the substrate, and a nozzle support member configured to support the nozzle;
a standby unit disposed to be spaced apart from the support unit, the standby unit configured to accommodate the nozzle and provide a contamination prevention liquid to the nozzle;
an imaging unit configured to capture an image of the nozzle including a discharge passage formed within the nozzle and a shape of the processing liquid; and
a detection unit configured to detect a position of a liquid level of the processing liquid or the contamination prevention liquid within the discharge passage from the image of the nozzle,
wherein the detection unit is configured to derive an edge profile by processing the image of the nozzle, to derive one or more search regions by dividing the edge profile, and to detect the liquid level within the one or more search regions.
